(19) United States
(12) Patent Application Publication
(10) Pub. No.: US 2024/0311279 A1
(43) Pub. Date: Sep. 19, 2024

(54) METHOD AND SYSTEM FOR GENERATING SCENARIO DATA FOR THE TESTING OF A DRIVER ASSISTANCE SYSTEM OF A VEHICLE

(71) Applicant: AVL LIST GMBH, Graz (AT)

(72) Inventor: Tobias DÜSER, Bühl (DE)

(21) Appl. No.: 18/548,810

(22) PCT Filed: Feb. 28, 2022
(86) PCT No.: PCT/AT2022/060055

§ 371 Date: Sep. 1, 2023

(30) Foreign Application Priority Data
Mar. 1, 2021 (AT) A 50138/2021

(51) Int. Cl. G06F 11/36; G06F 11/34

(52) U.S. Cl. CPC G06F 11/3684; G06F 11/3457; G06F 11/3664

(57) ABSTRACT

The invention relates to a system for generating scenario data for the testing of a driver assistance system of a vehicle and a corresponding method, where the system comprises: means for simulating a virtual traffic situation, where at least one first road user can be controlled by a first user and simulation data is generated during the simulation; a first user interface for outputting a virtual environment of at least one first road user to the first user on the basis of the virtual traffic situation; a second user interface for capturing inputs of the first user for controlling the at least one first road user in a virtual environment of the first road user; means for checking the generated simulation data for the occurrence of scenarios; means for extracting scenario data related to the scenario; and a data storage for recording the scenario data for testing the driver assistance system.

The invention relates to a computer-implemented method for generating scenario data for the testing of a driver assistance system of a vehicle. The invention further relates to a corresponding system.

The proliferation of driver assistance systems (Advanced Driver Assistance Systems—ADAS), which in a further development enables autonomous driving (Autonomous Driving—AD), keeps increasing in both the passenger car as well as the commercial vehicle sectors. Driver assistance systems make an important contribution to increasing active traffic safety and serve in enhancing driving comfort.

In addition to systems which in particular serve driving safety such as ABS (anti-lock braking system) and ESP (electronic stability program), a plurality of driver assistance systems are touted in the passenger and commercial vehicle sectors.

Driver assistance systems which are already being used to increase active road safety are park assist and adaptive automatic vehicle interval control, also known as Adaptive Cruise Control (ACC), which adaptively adjust a desired speed selected by a driver to the distance from a vehicle driving in front. A further example of such driver assistance systems are ACC stop-and-go systems which, in addition to ACC, effect the automatic further travel of the vehicle in a traffic jam or stationary traffic, lane departure warning or lane assist systems which automatically keep the vehicle in its lane, and pre-crash systems which for example ready or initiate braking in the event of a possible collision in order to draw the kinetic energy out of the vehicle as well as potentially initiate further measures should a collision be unavoidable.

These driver assistance systems increase safety in traffic by both warning the driver of critical situations as well as initiating autonomous intervention to avoid or minimize accidents, for example by activating an emergency braking function. Additionally, functions like automatic parking, automatic lane-keeping and automatic proximity control increase driving comfort.

A driver assistance system's gains in safety and comfort are only perceived positively by the vehicle's occupants when the aid provided by the driver assistance system is safe, reliable and—wherever possible—convenient.

Moreover, every driver assistance system, depending on its function, needs to handle given traffic scenarios with maximum safety for the vehicle itself and without endangering other vehicles or other road users respectively.

The respective degree of vehicle automation is divided into so-called automation levels 1 to 5 (see, e.g., the SAE J3016 standard). The present invention relates in particular to vehicles having driver assistance systems at automation level 3 to 5, which is generally considered autonomous driving.

There are many diverse challenges in testing such systems. In particular, a balance needs to be found between the testing effort and the testing coverage. The main task when testing ADAS/AD functions is thereby to demonstrate the guaranteed function of the driver assistance system in all conceivable situations, particularly including critical driving situations. Such critical driving situations involve a certain degree of danger since no reaction or a wrong reaction by the respective driver assistance system can lead to an accident.

The testing of driver assistance systems therefore requires allowing for a large number of driving situations which may arise in different scenarios. The range of possible scenarios thereby generally spans many dimensions (e.g. different road characteristics, behavior of other road users, weather conditions, etc.). From this virtually infinite and multidimensional range of parameters, it is particularly relevant in the testing of driver assistance systems to extract those parameter constellations for critical scenarios which can lead to unusual or dangerous driving situations.

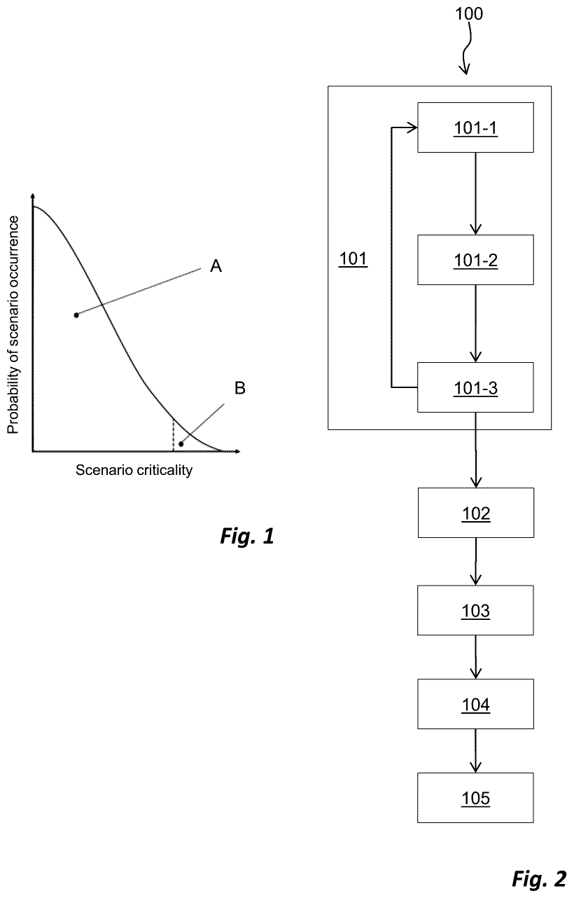

As depicted in FIG. 1, such critical scenarios have afar lower probability of occurrence than normal scenarios.

In order to validate a corresponding driver assistance system, scientific publications consider that operating a vehicle in autonomous driving operation is only statistically safer than a human-controlled vehicle when the respective driver assistance system has completed 275 million miles of accident-free driving. Real test drives cannot actually realize this, particularly considering the very tight development cycles and quality standards required in the automotive industry. For the aforementioned reason, it would also be unlikely that a sufficient number of critical scenarios, or driving situations resulting from these scenarios respectively, would be incorporated.

Using real test drive data from a real fleet of test vehicles to validate and verify driver assistance systems and to extract scenarios from the recorded data is known from the prior art. Furthermore, using full factorial designs for validation and verification is also known.

One task of the invention is that of being able to test driver assistance systems, in particular autonomous driving functions, in a plurality of scenarios. Particularly a task of the invention is generating scenarios for the testing of driver assistance systems.

This task is solved by the teaching of the independent claims. Advantageous embodiments are found in the dependent claims.

A first aspect of the invention relates to a computer-implemented method for generating scenario data for the testing of a driver assistance system of a vehicle having the following work steps:
generating simulation data by means of the following substeps:
simulating a virtual traffic situation having a plurality of virtual road users, wherein at least one first road user of the plurality of road users can be controlled by a first user and wherein those road users not able to be controlled by users are automatically controlled, in particular by artificial intelligence or by logic-based control,
outputting a virtual environment of the at least one first road user on the basis of the virtual traffic situation to the first user via a first, in particular an at least visual, user interface, and
capturing inputs of the first user for controlling the at least one first road user in the virtual environment of the first road user via a second user interface, wherein the captured inputs of the first user and the resulting interaction of the at least one first road user with its virtual environment are factored into the simulating of the virtual traffic situation,
checking the generated simulation data for the occurrence of scenarios arising from the interaction of the at least one first road user with the virtual environment, wherein the occurrence of the scenarios is characterized by a predefined constellation of simulated measured variables preferably corresponding to elementary maneuvers;
extracting scenario data related to the scenario upon occurrence of a scenario being determined; and
recording the scenario data for the testing of the driver assistance system.

Preferably, the extracted scenario data is output. Preferably, this ensues via a user interface or a data interface.

A user within the meaning of the invention is a natural person; i.e. a human.

A driver assistance system within the meaning of the invention is preferably configured to support a driver during the process of driving or at least partially control a vehicle, in particular a driver assistance system at automation level 3 to 5 or, further particularly, an autonomous driving function.

A road user within the meaning of the invention is preferably any object taking an active part in traffic. In particular, a road user is a person, an animal or a vehicle.

Extraction within the meaning of the invention preferably denotes a segregating or isolating.

In particular, scenarios are segregated or respectively isolated from the scenario data. Data ranges are thereby preferably selected within the scenario data.

Scenario data within the meaning of the invention is preferably characterized by the position and movement of the road users and the position of static objects in respect of a scenario.

A scenario within the meaning of the invention is preferably formed from a chronological sequence of, in particular static, scenes. The scenes thereby indicate, for example, the spatial arrangement of the at least one other object relative to the ego object, e.g. the constellation of road users. A scenario preferably factors in dynamic and static content. Preferably, a model for the systematic description of scenarios is used here, further preferably the model of the PEGASUS project (https://www.pegasusprojekt.de) with the following six independent layers: 1. road (geometry, . . . ); 2. road furnishings and rules (traffic signs, . . . ); 3. temporary modifications and events (road construction, . . . ); 4. moving objects (traffic-relevant objects such as: vehicles, pedestrians, . . . moving relative to the vehicle under testing); 5. environmental conditions (lighting situation, road weather, . . . ); 6. digital information (V2X, digital data/map, . . . ). A scenario can in particular include a driving situation in which a driver assistance system at least partially controls the vehicle equipped with the driver assistance system, called the ego vehicle, e.g. autonomously performs at least one vehicle function of the ego vehicle.

A traffic situation within the meaning of the invention preferably describes the totality of all the road user circumstances in traffic within a defined spatial area and/or defined period of time or point in time. Preferably, these road user circumstances are factored into the selection of applicable behavioral patterns at a specific point in time. Preferably, a traffic situation includes all relevant conditions, possibilities and determinants of actions. Although not imperative, a traffic situation can be represented from the point of view of a road user or object.

The simulated measured variables within the meaning of the invention are preferably selected from the following group: road user speed, in particular an initial speed; direction of movement, in particular a road user's trajectory; lighting conditions; weather; road surface; temperature; number and position of static and/or dynamic objects; speed and direction of movement, in particular trajectory, of the dynamic objects; condition of signaling systems, in particular traffic light systems; traffic signs; number of lanes; acceleration or braking deceleration of road users or objects.

A predefined constellation of measured variables within the meaning of the invention is preferably a constellation of values of one or more measured variables, particularly in a chronological sequence.

Labeling within the meaning of the invention preferably means the providing of a categorizing designation.

Scenario dangerousness within the meaning of the invention preferably denotes the spatial or temporal proximity to a traffic situation without any possible accident-free outcome (by one's own efforts and in consideration of the noted uncertainties). When an accident can no longer be avoided, the dangerousness is at its maximum. Preferably, dangerousness is also referred to as criticality. When the driving behavior or driving ability of a driver assistance system is taken into account, dangerousness can characterize a probability of an accident and/or a calculated duration up to a point in time of collision. Maximum dangerousness preferably exists when the calculated duration is 0 seconds and/or the accident probability is P=1. An increased accident probability can in particular be triggered by a driving maneuver, for example an evasive reaction or pronounced gradient changes during steering, braking, accelerating (thus e.g. a vehicle swerving due to sharp steering). An increased accident probability, in particular with respect to the other road users (in logic or AI-based guidance) and in a critical driving situation, can also force contravention of its driving task or its actual trajectory respectively (through an evasive maneuver). An increased accident probability can in particular also be caused by external factors affecting the first road user or the other road users, for example when a driver is blinded. A quality factor within the meaning of the invention preferably characterizes the simulated scenario. A quality factor is preferably understood as a quality or nature and/or a relevance of the simulated scenario in relation to the dangerousness of a driving situation for a specific driver assistance system.

Relevance within the meaning of the invention is preferably understood as the frequency at which a scenario occurs in road traffic. For example, a backlit scenario is more relevant than a scenario in which an airplane lands on the roadway. The relevance preferably also depends on the region for which the road traffic is relevant. For example, there are scenarios which are relevant in Germany but not in China.

An environment of the vehicle within the meaning of the invention is preferably formed at least by the road users and other objects relevant to the vehicle guidance provided by the driver assistance system. In particular, the environment of the vehicle encompasses scenery and dynamic elements. The scenery preferably includes all stationary elements.

The invention is based on the approach of using real people to generate scenarios, however without requiring any test drives in real traffic.

According to the invention, at least one real driver in each case maneuvers a vehicle within a virtual environment. The invention enables a crowdsourcing approach to generating scenarios. One or more users can now navigate a road user of their choice through virtual traffic situations on a simulator. Due to the virtually endless possibility of navigating options for the road user(s) as well as other aleatory mechanisms when simulating the virtual traffic situation, a virtually endless number of different scenarios can occur, just like in real traffic. The invention uses predefined criteria to determine between occurrences of known or new scenarios. To that end, the simulation process and in particular the simulation data generated therefrom are continuously analyzed/monitored.

The crowdsourcing approach can thereby capitalize on people's natural play instinct. The inventive method or even a suitable system can thus be provided to users. These users can then drive around in the simulated traffic “for fun.” Alternatively, tasks could also be set for the users, for example getting from point A to point B as quickly as possible while observing traffic regulations or having to collect certain objects. Furthermore, the user could be distracted when navigating through the simulated traffic, e.g., needing to provide specific vocal inputs or the like.

The simulation physics thereby correspond to reality so as to generate the most realistic scenario data possible. This applies in particular to the physical properties of the road users and those of the environment. Driving through objects or the like is not possible. Particularly preferentially, a plurality of users navigate a plurality of road users in the simulated traffic.

In one advantageous embodiment of the method, the scenario data thereby generated is already labeled, in particular objects of the virtual traffic situation are labeled. Information about object properties is available in the simulation so that the information can be associated with the objects.

This is particularly an advantage over data from a real test operation in which all the objects need to be labeled. This labeling is generally very laborious since it can only be done by actual people.

In a further advantageous embodiment of the method, the scenario data is described during extraction such that it can be used to simulate scenarios, preferably using OpenSCENARIO® or as an OSI data output. The scenario data can thereby still be used directly to simulate scenarios.

In a further advantageous embodiment of the method, the user is prompted to perform activity by various actions in the simulated virtual traffic environment. Such activity can be the simulated behavior of another road user, for example. In particular, these other road users could behave in such a way that the user is forced to react.

In a further advantageous embodiment, same also has the following work steps: determining a quality factor for the extracted scenario data as a function of a predefined criterion, whereby the quality factor is preferably characterized by the dangerousness of an underlying scenario. The quality factor indicates the quality of an underlying scenario. Preferably, the extracted scenario data is output when the quality factor reaches an abort condition. Further preferably, the quality factor is output to the user via a first or second user interface, particularly a display. An abort condition can thereby preferably be a calculated duration of time until the point in time of a collision or collision probability.

In a further advantageous embodiment of the invention, the quality factor is higher the more dangerous the respective scenario, in particular the shorter the calculated duration until a time point of collision.

In a further advantageous embodiment of the method, the first user is credited with a reward, in particular a notional reward, as a function of a resultant scenario's quality factor. This thereby gives the user motivation to create critical scenarios.

In a further advantageous embodiment of the method, a traffic flow model, in particular PTV-Vissim® or Eclipse SUMO, particularly version 1.8.0, is used to simulate the virtual traffic situation. Using a traffic flow model enables the generating of a particularly realistic traffic situation.

The features and advantages mentioned above in relation to the first aspect of the invention also apply correspondingly to the other aspects of the invention and vice versa.

A second aspect of the invention relates to a computer-implemented method for the testing of a driver assistance system of a vehicle having the following work steps:
providing scenario data characterizing a scenario in which the vehicle is situated and which has a plurality of other road users, wherein the scenario data is generated by means of a method for generating scenario data according to the first aspect of the invention;
simulating a virtual environment of the vehicle from the provided scenario data;
outputting the virtual environment to the driver assistance system via an interface; and
operating the driver assistance system in the virtual environment of the vehicle.

In one advantageous embodiment of the method for testing a driver assistance system, the driver assistance system is simulated. This means that, in accordance with the “software-in-the-loop” concept, only the software, or the actual code of the driver assistance system respectively, is considered or respectively implemented when simulating the virtual traffic situation. This thereby enables pure simulation-based testing of a driver assistance system.

In a further advantageous embodiment of the method for testing a driver assistance system, data relating to the environment of the vehicle is fed into the driver assistance system during the operation of the driver assistance system and/or the driver assistance system, in particular its sensors, is stimulated on the basis of the vehicle's environment. Doing so enables the testing of the driver assistance system, in particular its software or the entire hardware, on a test bench. In particular, a hardware-in-the-loop method can be employed to that end.

A third aspect of the invention relates to a system for generating scenario data for the testing of a driver assistance system of a vehicle which comprises:
means for simulating a virtual traffic situation having a plurality of virtual road users, wherein at least one first road user of the plurality of road users can be controlled by a first user and wherein those road users not able to be controlled by users are automatically controlled, in particular by artificial intelligence or by logic-based control, wherein simulation data is generated during the simulation;
a first, in particular at least visual, user interface for outputting a virtual environment of at least one first road user to the first user on the basis of the virtual traffic situation; and
a second user interface for capturing inputs of the first user for controlling the at least one first road user in a virtual environment of the first road user, wherein the simulating means is further configured to factor the captured inputs of the first user and the resulting interaction of the at least one first road user with its virtual environment into the simulating of the virtual traffic situation;
means for checking the generated simulation data for the occurrence of scenarios arising from the interaction of the at least one first road user with the rest of the environment, wherein the occurrence of the scenarios is characterized by a predefined constellation of simulated measured variables preferably corresponding to elementary maneuvers;
means for extracting scenario data related to the scenario upon occurrence of a scenario being determined by the means for checking the generated simulation data; and
a data storage for recording the scenario data for testing the driver assistance system.

A means within the meaning of the invention can be designed as hardware and/or software, in particular as a processing unit, particularly a digital processing unit, in particular a microprocessor unit (CPU), preferably data-connected or signal-connected to a memory and/or bus system and/or having one or more programs or program modules. The CPU can be configured to process commands implemented as a program stored in a memory system, capture input signals from a data bus and/or send output signals to a data bus. A memory system can comprise one or more, in particular different, storage media, particularly optical, magnetic, solid-state and/or other non-volatile media. The program can be designed so as to embody or be capable of performing the methods described herein such that the CPU can execute the steps of such methods and then in particular generate scenarios.

A fourth aspect of the invention relates to a system for testing a driver assistance system of a vehicle, comprising:
a data storage for providing scenario data characterizing a scenario in which the vehicle is situated and which has a plurality of other road users, wherein the scenario data is generated by means of a method according to one of claims 1 to 8;
means for simulating a virtual environment of the vehicle based on the scenario data; and
an interface for outputting the virtual environment to the driver assistance system such that the driver assistance system can be operated in the virtual environment of the vehicle on the basis of the simulated scenario.

Further aspects of the invention relate to a computer program containing commands which, when run on a computer, prompts it to execute a method according to the first or second aspect of the invention.

Further features and advantages are yielded by the following description of exemplary embodiments referencing the figures. Shown therein at least partly schematically:

FIG. 1 a diagram of scenario occurrence probability as a function of their criticality;

FIG. 2 a block diagram of an exemplary embodiment of a method for generating scenarios;

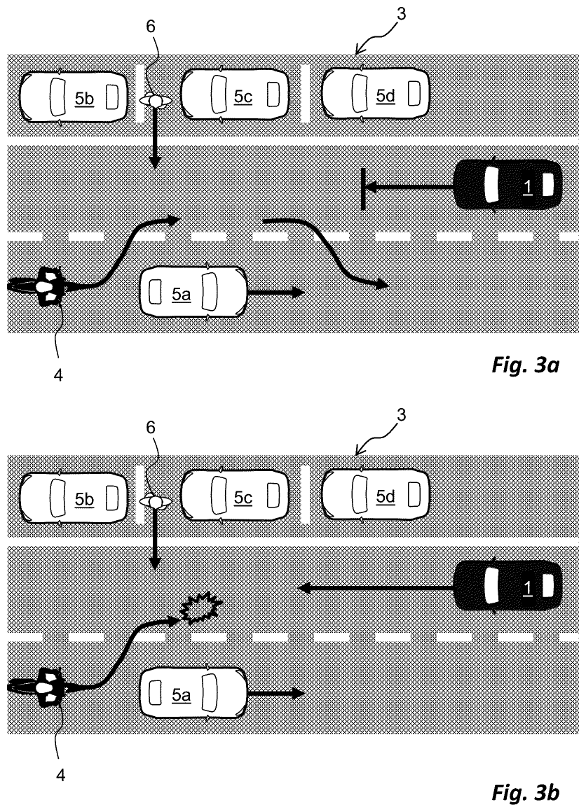

FIG. 3a a first example of a simulated virtual traffic situation;

FIG. 3b a second example of a simulated virtual traffic situation;

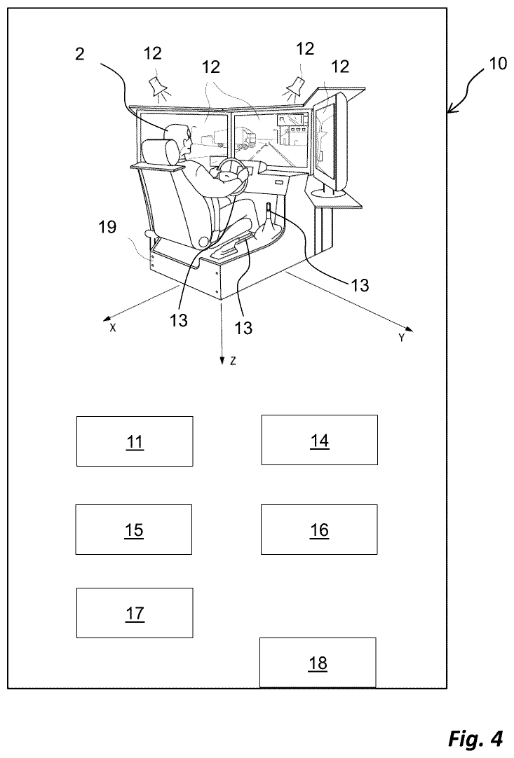

FIG. 4 an exemplary embodiment of a system for generating scenario data for testing a driver assistance system of a vehicle;

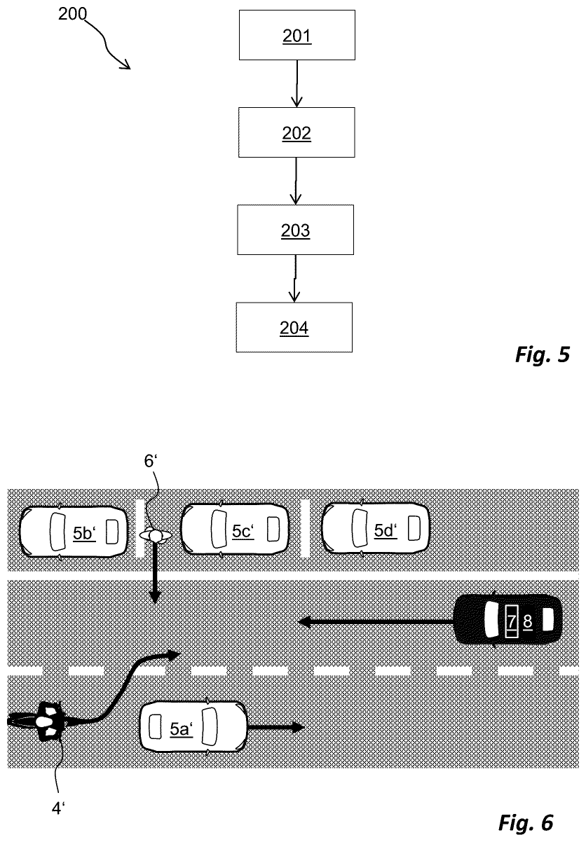

FIG. 5 a block diagram of an exemplary embodiment of a method for the testing of a driver assistance system of a vehicle;

FIG. 6 an example of a simulated scenario; and

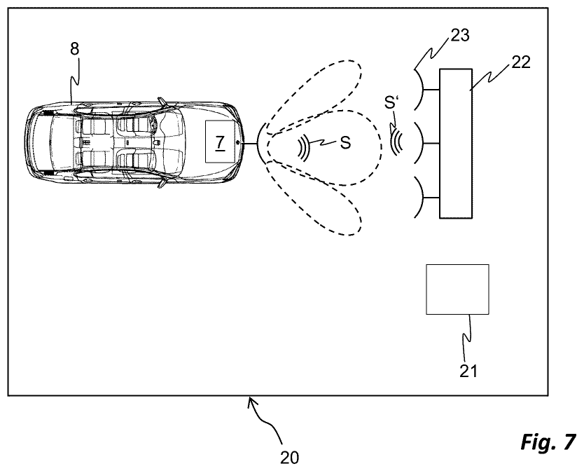

FIG. 7 an exemplary embodiment of a system for testing a driver assistance system of a vehicle.

FIG. 1 shows the probability of occurrence of scenarios as a function of scenario criticality. The probability of occurrence is the probability at which scenarios occur in actual road traffic.

Noticeable in FIG. 1 is that the majority of scenarios are of comparatively low complexity and/or criticality, which also corresponds to the general life experience of a motorist. The range of these scenarios is designated “A” in FIG. 1. In contrast, scenarios of high complexity and/or criticality, their range designated “B” in FIG. 1, occur comparatively infrequently. Yet it is precisely those “B” scenarios of great complexity and/or criticality which are highly relevant to analyzing the functionality of driver assistance systems.

Therefore, obtaining a sufficient number and diversity of different scenarios of high “B” complexity during the testing of a driver assistance system requires running a very large number of scenarios based on the distribution curve as shown.

A method for generating a large number of different scenarios for testing driver assistance systems is described below with reference to FIG. 2 to FIG. 3b.

Simulation data is generated in a first work step 101. Preferably, the first work step 101 comprises three sub-processes.

A virtual traffic situation 3 having a plurality of virtual road users 1, 4, 5a, 5b, 5c, 5d, 6 is simulated in the first of these processes 101-1. Preferably, at least one first road user 1 of the plurality of road users 1, 4, 5a, 5b, 5c, 5d, 6 can be controlled by a first user 2 (see FIG. 4) and those road users 4, 5a, 5b, 5c, 5d, 6 not able to be controlled by users are controlled automatically in this virtual traffic situation 3. Preferably an artificial intelligence, a logic-based model or a traffic flow model, particularly PTV-Vissim® or Eclipse SUMO, is thereby employed. Preferably, there can be a plurality of road users controlled by users; i.e. humans, in the simulated virtual traffic situation 3.

There are substantially two approaches relative to simulating the virtual traffic situation: The simulation is based on data obtained in a real test drive. In this case, the parameters of individual objects, e.g. their road user speed, can be changed or also adopted as captured during the real test drive. In an alternative embodiment of the method, the traffic situation 3 is generated purely on the basis of mathematical algorithms. Preferably, there can also be a mix of the two approaches.

An example of such a simulated traffic situation 3 is shown in FIG. 3a. In the traffic situation 3 shown in FIG. 3a, a pedestrian 6 is crossing a road. A vehicle 1, which is controlled by the first user, approaches the pedestrian 6 in the lane to the side of the pedestrian 6. Other vehicles 5b, 5c, 5d are parked alongside the traffic lane, making the pedestrian 6 not or only poorly visible to a driver of the vehicle 1 controlled by the user. A further vehicle 5a level with the pedestrian 6 is driving in the second lane for oncoming traffic. A motorcyclist 4 is approaching behind the other vehicle 5a and preparing to pass said other vehicle 5a. Whether this motorcyclist 4 is visible to the driver of the vehicle controlled by the first user cannot be deduced from FIG. 3a.

The other vehicles 5a, 5b, 5c, 5d, the pedestrian 6 as well as the motorcyclist 4 form a virtual environment of the vehicle 1 controlled by the first user 2 in traffic situation 3.

Based on how the first user 2 reacts or acts in the initial scenario which results from traffic situation 3; i.e., which driving behavior the first user exhibits in the virtual environment of the vehicle 1 he controls, a dangerous or less dangerous driving situation or other scenario will result. For example, if the first user 2 brakes vehicle 1 to a stop, as indicated in FIG. 3a by the bar in front of the movement arrow of vehicle 1, the motorcyclist 4 can then pass the oncoming vehicle 5a in the other lane 5a without any trouble.

FIG. 3b shows the same virtual traffic situation 3 as FIG. 3a in which the vehicle controlled by the first user 1 is in the same initial scenario as in FIG. 3a. As indicated by the movement arrow coming off of the vehicle 1 controlled by the first user, the first user continues driving vehicle 1 at undiminished speed.

Given this, it is highly probable that a subsequent driving situation or subsequent scenario will develop in which the motorcyclist 4 collides with the vehicle 1 driven by the first user 1. This is also indicated in FIG. 3b. Such a driving situation/scenario would correspond to very high dangerousness.

In a second process 101-2 of the first work step 101, the virtual traffic situation 3 is output to the first user 2 via a first user interface 12.

Examples of possible user interfaces are shown in FIG. 4 and preferably include visual user interfaces, in particular screens, audio user interfaces, in particular speakers, and/or a user interface for stimulating the sense of balance of first user 2.

In a third process 101-3 of the first work step 101, inputs of the first user 2 for controlling the at least one road user in a virtual environment of the first road user 1 are captured via a second user interface 13.

The second user interfaces 13 as well are shown in FIG. 4. Preferably, these relate to the steering wheel, a gear shift, a handbrake, a brake pedal, a clutch and/or a gas pedal as well as other possible control instruments available to a driver in a vehicle.

Depending on the type of road user 1, 4, 5a, 5b, 5c, 5d, 6 controlled by user 2, however, other input means can also be provided as the user interface 13, for example a type of joystick.

As explained above, the first road user 1 in FIGS. 3a and 3b is the black vehicle. The captured inputs of the first user 2 and the resulting interaction of vehicle 1; i.e., the first road user, with its virtual environment factor into the simulating of the traffic situation 3 shown in FIGS. 3a and 3b.

The interaction in the traffic situations 3 shown in FIGS. 3a and 3b is, for example, how the first user 2 reacts to the initial scenario. Depending on the reaction of the first user 2 to this initial scenario, the other road users, in particular the other oncoming vehicle 5a and the motorcyclist 4 as well as the pedestrian 6, will also react. For example, it is to be expected that the motorcyclist 4 will brake when he notices that the vehicle 1 controlled by the first user 2 is not reducing its speed. These interactions in turn influence the development of the virtual traffic situation 3.

The work step of generating 101 simulation data is therefore a continuous process which, as indicated in FIG. 2, continually runs in a loop and thereby generates simulation data.

During the simulation, the objects which are part of the virtual traffic situation 3 are already marked with meta information. There is therefore no need for a separate label. This relates to both static and dynamic objects. Subsequent data able to be obtained from the simulation data thereby includes the so-called ground truth information.

When the scenario data is used to test a driver assistance system, for example, one can follow which objects the driver assistance system correctly detected and which it incorrectly detected. Examples of such labels are tree, pedestrian, passenger car, truck, etc.

Further preferably, actions are set in the driving situations 3 which prompt activity from the first user. For example, in the driving situation 3 of FIGS. 3a and 3b, this could be a vehicle driving behind the vehicle 1 driven by the first user 2 and coercing it to accelerate. An unexpected movement trajectory of the pedestrian 6, for example should he start to run, can also be such an action.

In a second work step 102 of the method 100, the generated simulation data is checked for the occurrence of scenarios arising from the interaction of the at least one first road user 1, the black vehicle in FIGS. 3a and 3b, with the virtual environment. Both already known scenarios which have previously occurred or are predefined as templates as well as scenarios not yet predefined can thereby be checked.

Both types of scenarios are preferably defined by predefined constellations of simulated measured variables able to be determined from the virtual traffic situation 3. These predefined constellations either form the templates for scenarios or correspond to elementary maneuvers from which the occurrence of a scenario can be inferred. This could be a strong braking deceleration of vehicle 1 in FIGS. 3a and 3b, for example, this being used as a trigger condition for the occurrence of a scenario not yet having been predefined.

Upon determining that a scenario has occurred, scenario data pertaining to the scenario is extracted in a third work step 103. In this context, extraction in particular denotes segregating or isolating a data range in the simulation data which is related to the determined scenario. Preferably, the scenario data is delineated during extraction so as to be suitable for simulating scenarios. Preferably, the data can be used with OpenSCENARIO® or OpenDrive®. Further preferably, it can be output as OSI data or OSI stream.

In a fourth work step 104 of method 100, the scenario data for testing the driver assistance system is recorded. This data is thereafter available for testing a driver assistance system. Such a testing method 200 is described further below with reference to FIG. 5.

In a fifth work step 105, preferably a quality factor of the resulting scenario is determined as a function of a predefined criterion, wherein the quality factor is preferably characterized by the dangerousness of one of the scenarios. Preferably, the more dangerous the resulting scenario, the higher the quality factor.

Dangerousness is preferably determined by so-called “time-to-X” metrics such as described for example in the “Metrics for assessing the criticality of traffic situations and scenarios” publication; P. Junietz et al., “11th Driver Assistance Systems and Automated Driving Workshop,” FAS 2017. Particularly thereby able to be used as criteria: duration of time until a point of collision (time-to-collision), time-to-kickdown, time-to-steer, time-to-react, distance-of-closest-encounter, time-to-closest-encounter, worst-time-to-collision. Further preferably, the dangerousness is characterized by probability of an accident.

Further preferably, the first user 2 is credited with a reward, in particular a notional reward, as a function of a presented scenario's quality factor.

FIG. 4 depicts a system 10 for generating scenarios for testing a driver assistance system of a vehicle.

This system 10 preferably comprises means 11 for simulating a virtual traffic situation 3 having a plurality of virtual road users. In order for road users 1 to be made controllable by a first user 2, the system further comprises at least one first user interface 12 and at least one second user interface 13.

The at least one first user interface 12 serves in outputting a virtual environment of at least one first road user 1 to the first user 2. The virtual environment of the at least one first road user 1 is thereby determined on the basis of the simulated virtual traffic situation 3. This is thereby substantially a representation of the virtual traffic situation 3 in the initial scenario from the perspective of the first road user 1 as controlled by the first user 2.

As FIG. 4 depicts, these user interfaces 12 are visual user interfaces such as screens and audio interfaces such as speakers and possibly also apparatus able to affect the sense of balance of the respective user 2.

The second user interface, user interfaces 13 respectively, are configured to capture inputs from the respective user 2. As FIG. 4 shows, these relate preferably to different operating elements. As already explained above, they can be dependent on the respective road user 1 controlled by the user 2. If the road user 1 controlled by the first user 2 is a vehicle, the user interfaces 12, 13 are preferably arranged in the area of a so-called seat box 19 which, as depicted in FIG. 4, forms a simulator together with the user interfaces 12, 13.

The system 10 preferably further comprises means 14 for checking the generated simulation data for the occurrence of scenarios. Furthermore, the system 10 preferably comprises means 15 for extracting scenario data related to the scenario as well as a data storage 16 for recording the scenario data. Further preferably, the system 10 preferably comprises means for determining a quality factor of the extracted scenario data as a function of a predefined criterion. Further preferably, the system 10 has a further interface 18 preferably configured as a user interface for outputting the quality factor to the user 2 and/or a data interface for outputting the scenario data for further processing. Preferably, means 11, 14, 15, 16, 17, 18 are part of a data processing device preferably formed by a computer.

FIG. 5 shows a flow chart of an exemplary embodiment of a method 200 for the testing of a driver assistance system 7 of a vehicle 8 as depicted in FIG. 6.

A first work step 201 of this method 200 entails the simulating of scenario data which characterizes a scenario in which the vehicle 8) is situated and which preferably comprises a plurality of other road users 4′, 5a′, 5b′, 5c′, 5d′, 6′. This scenario data as well is preferably based in turn on simulations from which it was extracted according to the method 100 described above.

On the basis of the scenario data, a scenario is simulated in a second work step 202. This scenario has the vehicle 8 with the driver assistance system 7 under testing. Moreover, the scenario preferably comprises a plurality of other road users or objects.

In the scenario example depicted in FIG. 6, these are, analogous to the driving situations 3 shown in FIG. 3a, 3b, parked vehicles 5b′, 5c′, 5d′, a pedestrian 6′, an oncoming vehicle 5a′ in the other lane as well as a motorcycle 5′ likewise situated in said lane.

On the basis of the simulated scenario, a virtual environment of the vehicle 8 with the driver assistance system 7 is generated and output in a third work step 203.

The virtual environment is output to the driver assistance system 7 via interface 23 in the third work step 203. Lastly, the driver assistance system 7 is operated in the virtual environment of vehicle 8 in a fourth work step 204.

The driving behavior of the driver assistance system 7 in the scenario or environment respectively can be further analyzed and assessed. The driver assistance system 7 can be optimized on the basis of such an analysis or assessment.

In the scenario shown in FIG. 6, the driver assistance system 7 of a vehicle 8 comprises a radar system which detects the objects located in the area surrounding the vehicle 8, in particular road users 4′, 5a′, 5b′, 5c′, 5d′, 6′.

In the example scenario as depicted, the driver assistance system 7 is integrated into the passenger vehicle 8. However, the driver assistance system to be tested could likewise be integrated into the motorcycle 4′. For example, the motorcyclist could be warned in advance by sensors of the driver assistance system and thus not pull out. Thus, the driver assistance system of the motorcycle 4′ reacts and the black car can continue without there being a collision. A system 20 for testing a driver assistance system 7 which is suited to executing the method 200 described with respect to FIGS. 5 and 6 is depicted in FIG. 7.

Such a system 20 comprises a data storage 21 for providing scenario data characterizing a scenario in which the vehicle 8 is situated. Means 22 are configured to simulate a virtual environment of the vehicle on the basis of the scenario data. Furthermore, the means 22 is also configured to render the environment.

Lastly, an interface 23 is configured to output the virtual environment of a driver assistance system 7. If the driver assistance system 7 has an optical camera, such an interface can be a screen. In the example depicted in FIG. 7, the sensor of the driver assistance system is a radar sensor which emits a signal S. This signal S is picked up by radar antennas 23.

Based on the acquired signal and the simulated environment, the simulating means 22 calculates a response signal S′ which is in turn output to the radar of the driver assistance system. So doing enables testing the function of the driver assistance system 7. Depending on which components of a driver assistance system 7 are to be tested, the simulated virtual environment can be tested by emulating signals to the sensor of the driver assistance system 7, as shown in FIG. 7. Alternatively, however, a signal fed directly into the data processing unit 7 of the driver assistance system can also be generated as well as a signal S′ which is only processed by the software of the driver assistance system 7.

Preferably, the data storage 21 and the simulating means 22 are part of a data processing device.

It should be noted that the exemplary embodiments are only examples which are in no way intended to limit the scope of protection, application and configuration. Rather, the foregoing description is to provide the person skilled in the art with a guideline for implementing at least one exemplary embodiment, whereby various modifications can be made, particularly as regards the function and arrangement of the described components, without departing from the scope of protection as results from the claims and equivalent combinations of features.

What is claimed is:

1. A computer-implemented method for generating scenario data for the testing of a driver assistance system of a vehicle having the following work steps:
generating simulation data by:
simulating a virtual traffic situation having a plurality of virtual road users, wherein at least one first road user of the plurality of road users can be controlled by a first user and wherein those road users not able to be controlled by users are automatically controlled, in particular by artificial intelligence or by logic-based control,
outputting a virtual environment of the at least one first road user on the basis of the virtual traffic situation to the first user via a first, in particular an at least visual, user interface, and
capturing inputs of the first user for controlling the at least one first road user in the virtual environment of the first road user via a second user interface, wherein the captured inputs of the first user and the resulting interaction of the at least one first road user with its virtual environment are factored into the simulating of the virtual traffic situation;
checking the generated simulation data for the occurrence of scenarios arising from the interaction of the at least one first road user with the virtual environment, wherein the occurrence of the scenarios is characterized by a predefined constellation of simulated measured variables preferably corresponding to elementary maneuvers;
extracting scenario data related to the scenario upon occurrence of a scenario being determined; and
recording the scenario data for the testing of the driver assistance system.

2. The method according to claim 1, wherein objects of the virtual traffic situation are labeled.

3. The method according to claim 1, wherein the scenario data is described during extraction such that it can be used to simulate scenarios, preferably using OpenSCENARIO® or as an OSI data output.

4. The method according to claim 1, wherein the first user is prompted to perform activity by an action or actions in the simulated virtual traffic environment.

5. The method according to claim 1, further comprising the following work step:
determining a quality factor for the extracted scenario data as a function of a predefined criterion, wherein the quality factor is preferably characterized by the dangerousness of an underlying scenario.

6. The method according to claim 5, wherein the quality factor is higher the more dangerous the respective scenario is, in particular the shorter the calculated duration until a time point of collision.

7. The method according to claim 1, wherein the first user is credited with a reward, in particular a notional reward, as a function of the quality factor of a resultant scenario.

8. The method according to claim 1, wherein a traffic flow model, in particular PTV Vissim®, is used to simulate the virtual traffic situation.

9. A computer-implemented method for the testing of a driver assistance system of a first vehicle having the following work steps:
providing scenario data characterizing a scenario in which the first vehicle is situated and which has a plurality of other road users,
wherein the scenario data is generated by means of a method according to claim 1;
simulating a virtual environment of the first vehicle from the provided scenario data;
outputting the virtual environment to the driver assistance system via an interface; and
operating the driver assistance system in the virtual environment of the first vehicle.

10. The method according to claim 9, wherein the driver assistance system is simulated.

11. The method according to claim 10, wherein data relating to the environment of the first vehicle is fed into the driver assistance system during the operation of the driver assistance system and/or the driver assistance system, in particular its sensors, is stimulated on the basis of the environment of the first vehicle.

12. A computer program containing commands which, when run on a computer, prompts it to execute the steps of a method according to claim 1.

13. A computer-readable medium on which a computer program according to claim 12 is stored.

14. A system for generating scenario data for the testing of a driver assistance system of a vehicle comprising:
means for simulating a virtual traffic situation having a plurality of virtual road users, wherein at least one first road user of the plurality of road users can be controlled by a first user and wherein those road users not able to be controlled by users are automatically controlled, in particular by artificial intelligence or by logic-based control, wherein simulation data is generated during the simulation;
a first, in particular at least visual, user interface for outputting a virtual environment of at least one first road user to the first user on the basis of the virtual traffic situation; and
a second user interface for capturing inputs of the first user for controlling the at least one first road user in a virtual environment of the first road user, wherein the simulating means is further configured to factor the captured inputs of the first user and the resulting interaction of the at least one first road user with its virtual environment into the simulating of the virtual traffic situation;
means for checking the generated simulation data for the occurrence of scenarios arising from the interaction of the at least one first road user with the rest of the environment, wherein the occurrence of the scenarios is characterized by a predefined constellation of simulated measured variables preferably corresponding to elementary maneuvers;
means for extracting scenario data related to the scenario upon occurrence of a scenario being determined by the means for checking the generated simulation data; and
a data storage for recording the scenario data for testing the driver assistance system.

15. A system for testing a driver assistance system of a first vehicle, comprising:
a data storage for providing scenario data characterizing a scenario in which the first vehicle is situated and which has a plurality of other road users, wherein the scenario data is generated by means of a method (100) according to claim 1;
means for simulating a virtual environment of the first vehicle based on the scenario data; and
an interface for outputting the virtual environment to the driver assistance system such that the driver assistance system can be operated in the virtual environment of the first vehicle on the basis of the simulated scenario.
